(19) United States
(12) Patent Application Publication
(10) Pub. No.: US 2008/0023808 A1
(43) Pub. Date: Jan. 31, 2008

(54) CHIP PACKAGE AND DIGITAL CAMERA MODULE USING SAME

(75) Inventors: CHIH-CHENG WU, Chu-Nan (TW); CHANG-KUO YANG, Chu-Nan (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: ALTUS TECHNOLOGY INC., Chu-Nan (TW)

(21) Appl. No.: 11/616,835

(22) Filed: Dec. 27, 2006

(30) Foreign Application Priority Data
Jul. 28, 2006 (CN) 200610061870.5

(51) Int. Cl. H01L 23/02

(52) U.S. Cl. 257/678

(57) ABSTRACT

A digital camera module (10) includes a chip package (20) and a lens module (50) mounted to the chip package. The package includes a carrier (21), a chip (23), a plurality of wires (24), an adhesive (26) and a cover (28). The carrier has a cavity (213) defined therein, an opening defined in a top surface, and a plurality of top contacts (215) arranged on the top surface around the opening. The chip is received in the cavity, and includes an active area (231) and a plurality of pads (233) disposed on a top surface thereof. The wires electrically connect each of the pads to a corresponding top contact of the carrier. The adhesive is applied to a peripheral circumference of the top surface of the chip around the active area. The cover is adhered to the adhesive, and encloses the active area of the chip cooperatively with the adhesive.

### CROSS-REFERENCE TO RELATED APPLICATIONS

This application is related to two co-pending U.S. patent applications (Attorney Docket No. US11426 and US11427), respectively entitled “CHIP PACKAGE AND DIGITAL CAMERA MODULE USING SAME” and “CHIP PACKAGE AND DIGITAL CAMERA MODULE USING SAME”, by Chih-Cheng Wu et al. Such applications have the same assignee as the present application and have been concurrently filed herewith. The above-identified applications are incorporated herein by reference.

### BACKGROUND

1. Technical field

The present invention generally relates to integrated circuit chip packages and digital camera modules using the package and, more particularly, to an image sensor chip package and a digital camera module using the package.

2. Description of the Related Art

Generally, digital cameras are image-recording media capable of photographing a plurality of still images without using film. Such a digital camera typically uses an image pickup device, which is a kind of semiconductor device, such as a charge coupled device (CCD) or complementary metal oxide semiconductor (CMOS). In the digital camera, an object image formed on the image pickup device through a lens is converted into an electrical signal by the image pickup device, and the electrical signal is stored as a digital signal in, for example, a mobile phone or personal digital assistant (PDA), in which the digital camera is mounted, or in a “stand-alone” digital still or video camera unit. In order to protect the image pickup device from contamination or pollution (i.e. from dust or water vapor), the image pickup device is generally sealed in a structural package.

FIG. 2 (related art) shows a typical digital camera module 80. The digital camera module 80 includes a substrate 81, a frame portion 82, a chip 84, a plurality of wires 85, a first adhesive 86, a cover 87, a second adhesive 88 and a lens module 89. The substrate 81 has a top surface, and a bottom surface provided with a plurality of output points 812. The frame portion 82 is disposed on the top surface of the substrate 81, thus the frame portion 82 and the substrate 81 cooperatively define a receiving cavity 83 therebetween. The frame portion 82 provides a plurality of input points 822 on a top surface thereof. Each input point 822 electrically connects with a respective output point 812 via a connecting device (not shown), such as plated through-holes, or conductive leads. The chip 84 is mounted in the receiving cavity 83. The chip 84 includes a plurality of pads 841 and an active area 843 arranged on a top surface thereof. The wires 85 electrically connect the pads 841 of the chip 84 to the input points 822 of the frame portion 82. The first adhesive 86 is applied to the top surface of the frame portion 82 and covers joints of the wires 85 and the input points 822. The cover 87 is attached to the top surface of the frame portion 82 via the first adhesive 86, thus sealing the chip 84 in the receiving cavity 83. The second adhesive 88 is applied to the cover 87 to fix the lens module 89 to the cover 87.

However, the frame portion 82 and the cover 87 cooperatively form a relatively large sealing space to seal the active area 843 of the chip 84, which results in more dust-particles adhering to the cover 87, the substrate 81 and the frame portion 82. Thus, more dust-particles will drop onto the chip 84. The dust-particles obscure the optical path and produce errors in the image sensing process. Accordingly, the quality and/or reliability of the digital camera module 80 may be adversely affected.

In addition, the adhesive 86 adheres the cover 87 to the frame portion 82, thus there is a risk that the cover 87 may be mounted at a slant to the frame portion 82 and the lens module 89 fixed to the cover 87 would correspondingly slanted, and an optical axis of the lens module 89 would displace from a center of the active area 843 of the chip 84. Furthermore, it is difficult to ensure that an optical axis of the lens module 89 is precisely aligned with a center of the active area 843 of the chip 84 when mounting the lens module 89 onto the frame portion 82. In cases where the optical axis of the lens module 89 is somehow displaced from the center of the chip 84 a distorted image will be projected onto the chip 84. Accordingly, the quality of images formed by the digital camera module 80 may be adversely affected.

Therefore, an improved chip package and an improved digital camera module are desired in order to overcome the above-described shortcomings.

### SUMMARY

In one aspect, a chip package is provided. The chip package includes a carrier, a chip, a plurality of wires, an adhesive and a cover. The carrier has a cavity defined therein, an opening defined in a top surface, and a plurality of top contacts arranged on the top surface around the opening. The chip is received in the cavity, and includes an active area and a plurality of pads disposed on a top surface thereof. The wires electrically connect each pad to a corresponding top contact of the carrier. The adhesive is applied to a peripheral circumference of the top surface of the chip, around the active area. The cover is adhered to the adhesive, and encloses the active area of the chip cooperatively with the adhesive.

In another aspect, a digital camera module is provided. The digital camera module includes a chip package and a lens module mounted to the chip package. The package includes a carrier, a chip, a plurality of wires, an adhesive and a cover. The carrier has a cavity defined therein, an opening defined in a top surface, and a plurality of top contacts arranged on the top surface around the opening. The chip is received in the cavity, and includes an active area and a plurality of pads disposed on a top surface thereof. The wires electrically connect each pad to a corresponding top contact of the carrier. The adhesive is applied to a peripheral circumference of the top surface of the chip around the active area. The cover is adhered to the adhesive, and encloses the active area of the chip cooperatively with the adhesive.

Other advantages and novel features will become more apparent from the following detailed description when taken in conjunction with the accompanying drawings.

### BRIEF DESCRIPTION OF THE DRAWINGS

Many aspects of the present chip package and digital camera module using same can be better understood with reference to the following drawings. The components in the drawings are not necessarily drawn to scale, the emphasis instead being placed upon clearly illustrating the principles of the chip package and digital camera module using same. Moreover, in the drawings, like reference numerals designate corresponding parts throughout the several views.

FIG. 1 is a schematic, cross-sectional view of a digital camera module having a chip package, according to a preferred embodiment; and

FIG. 2 is a cross-sectional view of a typical digital camera module having a chip package.

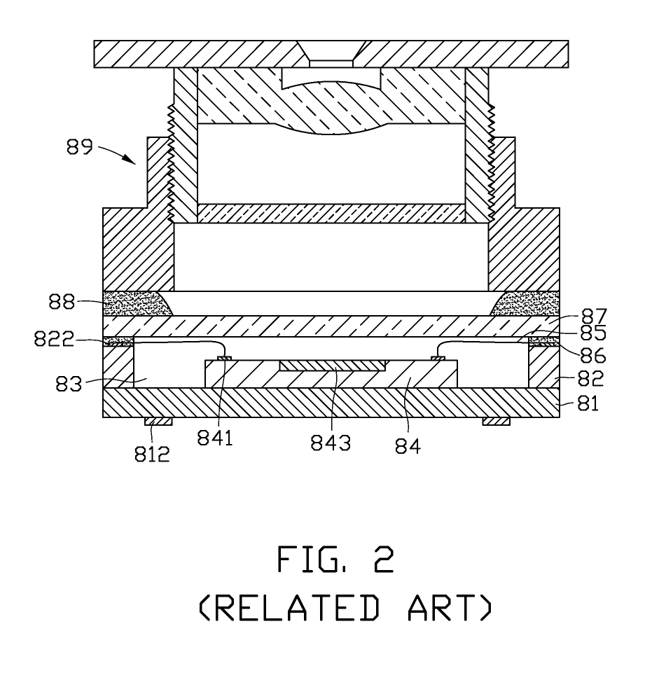

### DETAILED DESCRIPTION OF THE PERFERRED EMBODIMENT

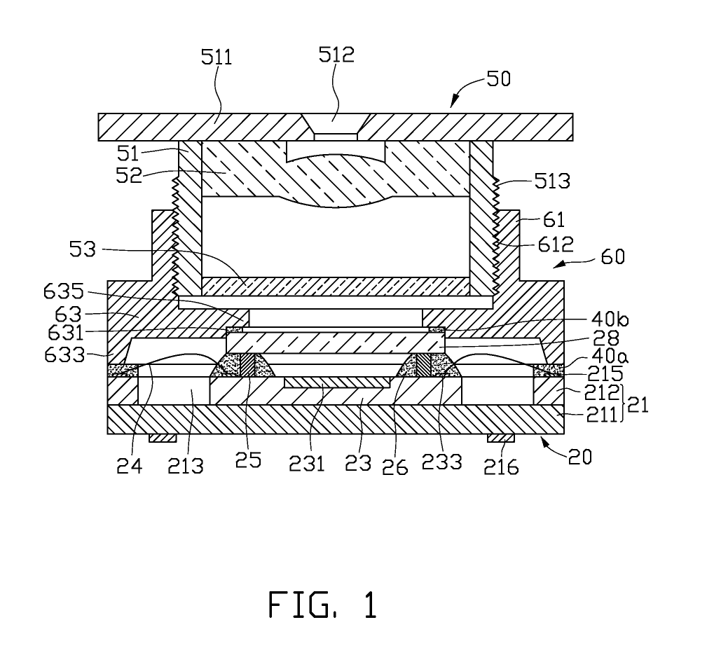

Referring to FIG. 1, a digital camera module 10 according to a preferred embodiment of the present invention is shown. The digital camera module 10 includes a chip package 20, a second adhesive 40a, 40b, a lens module 50, and a holder 60.

The chip package 20 includes a carrier 21, a chip 23, a plurality of wires 24, a supporting member 25, a first adhesive 26, and a cover 28.

The carrier 21 includes a base board 211, a sidewall 212 upwardly extending from a periphery of the base board 211, and a cavity 213 cooperatively formed by the base board 211 and the sidewall 212 for receiving electronic components. The cavity 213 defines an opening communication with ambient air. The carrier 21 further includes a plurality of top contacts 215 arranged on a top surface of the sidewall 212, and a plurality of bottom contacts 216 disposed on a bottom surface of the base board 211. The carrier 21 can have a one-piece shape, for example, the base board 211 and the sidewall 212 can be formed by injection molding. Alternatively, the carrier 21 can be assembled from a separate base board 211 and a separate sidewall 212. Each top contact 215 electrically connects with a corresponding bottom contact 216 via a respective interconnecting device (not shown). The top and bottom contacts 215, 216 are both configured for electrically connecting with other electronic components, for example the top contacts 215 can be used to electrically connect to a chip and the bottom contacts 216 can be used to electrically connect with a printed circuit board (PCB), thereby transmitting signals from the chip to the PCB via the interconnecting device. The interconnecting device can be plated through-holes or conductive leads electrically connecting the top contacts 215 to the bottom contacts 216.

The chip 23 can be, for example a complementary metal-oxide-semiconductor transistor (CMOS) image sensor, or a charge coupled device (CCD) image sensor, and is received in the cavity 213, and is attached to the base board 211. A top surface of the chip 23 is arranged with an active area 231 (e.g., a photo-registering zone) and a number of pads 233 arranged around the active area 231. The pads 233 are configured for electrically connecting with other electronic components to transmit electrical signals from the chip 23 to other electronic components.

The wires 24 can be made of a conductive material with good electric conductivity, such as gold or aluminum alloy. One end of each wire 24 is connected/joined with a respective pad 233 of the chip 23, and the other end of the wire 24 is connected/joined with a respective top contact 215 of the carrier 21.

The supporting member 25 is adapted for supporting the cover 28 above the top surface of the chip 23. According to the preferred embodiment, the supporting member 25 is a frame, and is disposed on the top surface of the chip 23, between the active area 231 and the pads 233. It is to be understood that the supporting member 25 can include four columns which are disposed at respective corners of the top surface of the chip 23.

The first adhesive 26 is applied to the top surface of the chip 23 along a peripheral circumference, and covers the supporting member 25 and connecting areas where the wires 24 connect/join with the pads 233. The first adhesive 26 can be further applied to the wires 24 in a manner so as to cover the whole of each wire 23 in order to protect the wires 23 from damage due to external force.

The cover 28 is transparent plate member made of glass or plastic so as to allow light to transmit therethrough, and is disposed above the top surface of the chip 23. The cover 28 is smaller than the opening of the cavity 213 of the carrier 21, and is larger than the active area 231 of the chip 23. The cover 28 is supported by the supporting member 25 so as to be spaced from the top surface of the chip 23 to avoid damaging the wires 23, and is adhered to the first adhesive 26. The cover 28 and the first adhesive 26 cooperatively define a sealing space to enclose the active area 231 of the chip 23.

The second adhesive 40a is applied to the top surface of the sidewall 212 of the carrier 21, and covers connecting areas where the wires 24 electrically connect with the top contacts 215. The second adhesive 40b is applied to a peripheral circumference of a top surface of the cover 28.

The lens module 50 includes a barrel 51, at least one lens 52 and a filter 53. The barrel 51 is a hollow cylinder for receiving the at least one lens 52 and the filter 53 therein, and has an external thread 513 formed on an external surface thereof. One end of the barrel 51 is covered by a plate 511 which has a transparent region 512 formed in a central portion thereof so that light can be transmitted therethrough.

The holder 60 includes a cylinder portion 61 configured (i.e., structured and arranged) for receiving the lens module 50, a seat portion 63 from which the cylinder portion 61 projects, and a through hole defined by the respective interiors of the cylinder portion 61 and the seat portion 633 and penetrating therethrough. The cylinder portion 61 has an internal thread 612 formed thereon for mating with the external thread 513 of the lens module 50. The seat portion 63 has an inner circumferential wall 631, a frame section 633 and a stopper ring 635. The inner circumferential wall 631 has a dimension approximately equal to that of the peripheral circumference of the cover 28. The frame section 633 axially extends from a periphery of an end of the seat portion 63, positioned opposite to the cylinder portion 61, for mounting with the carrier 21. The stopper ring 635 radially protrudes from the inner circumferential wall 631, and has an inner periphery which is of a size smaller than that of the peripheral circumference of the cover 28.

The seat portion 63 of the holder 60 receives the chip package 20 therein, wherein an end of the frame section 633 is adhered to the sidewall 212 of the carrier 21 via the second adhesive 40a, the inner circumferential wall 631 tightly contacts with a peripheral sidewall of the cover 28, and a bottom surface of the stopper ring 635 is adhered to the cover 28 via the second adhesive 40b. The cylinder portion 61 receives the lens module 50 therein, with the internal thread 612 of the cylinder portion 61 engaging with the internal thread 513 of the barrel 51. The at least one lens 52 faces toward the active area 231 of the chip 23 to form an image thereon.

In an alternative embodiment, the lens module 50 can be omitted so long as at least one lens is received in the cylinder portion 61 of the holder 60 to form a focused image on the active area 231 of the chip 23.

In the aforesaid chip package 20 of the digital camera module 10, the cover 28 and the first adhesive 26 cooperatively form a relative small sealing space to seal the active area 231 of the chip 23. Thus, the sealing space contains relatively little dust particles therein, the pollution and/or contamination of the active area 231 is reduced and the quality and reliability of the digital camera module 10 is much improved.

In addition, the cover 28 is supported by the supporting member 25, thus there is minimal risk that of the cover 28 being mounted at a slant. Furthermore, the inner circumferential wall 631 of the seat portion 63 of the holder 60 contacts with the peripheral wall of the cover 28, thus the holder 61 can be easily and precisely mounted to the chip package 20. Accordingly, the lens module 50 received in the holder 60 can be aligned with the chip 23. Therefore, the quality of the digital camera module 10 can be further improved.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A chip package comprising:
a carrier having a cavity defined therein, an opening defined in a top surface of the carrier communicating with the cavity, and a plurality of top contacts arranged on the top surface around the opening;
a chip received in the cavity, and comprising an active area and a plurality of pads disposed on a top surface thereof;
a plurality of wires electrically respectively connecting one of the pads to a corresponding top contact of the carrier; and
an adhesive applied to a peripheral circumference of the top surface of the chip, around the active area; and
a cover adhered to the adhesive, the cover and the adhesive cooperatively enclosing the active area of the chip.

2. The chip package as claimed in claim 1, further comprising a supporting member disposed on the top surface of the chip to support the cover.

3. The chip package as claimed in claim 2, wherein the supporting member is a frame member placed outside the active area of the chip.

4. The chip package as claimed in claim 2, wherein the supporting member comprises a plurality of columns each arranged at a respective corner of the top surface of the chip.

5. The chip package as claimed in claim 1, wherein the carrier comprises a base board, and a sidewall upwardly extending from the base board, and base board and the sidewall cooperatively form the cavity.

6. A digital camera module comprising:
a chip package comprising:
a carrier having a cavity defined therein, an opening defined in a top surface of the carrier communicating with the cavity, and a plurality of top contacts arranged on the top surface around the opening;
a chip received in the cavity, and comprising an active area and a plurality of pads disposed on a top surface thereof;
a plurality of wires electrically connecting one of the pads to a corresponding top contact of the carrier;
an adhesive applied to a peripheral circumference of the top surface of the chip, around the active area; and
a cover adhered to the adhesive, the cover and the adhesive cooperatively closing the active area of the chip; and
a lens module mounted to the chip package.

7. The digital camera module as claimed in claim 6, wherein the chip package further comprises a supporting member disposed on the top surface of the chip and supporting the cover.

8. The digital camera module as claimed in claim 6, wherein the lens module comprises a holder, the holder includes a cylinder portion for receiving at least one lens therein and a seat portion for attached on the carrier of the chip package.

9. The digital camera module as claimed in claim 8, wherein the seat portion comprises an inner circumference wall contacting with a sidewall of the cover, a frame section projecting therefrom to attach to the carrier, and a stopper ring radially extends from the inner circumference wall to be fixed to the cover.

10. The digital camera module as claimed in claim 8, wherein the at least one lens is fixed to a barrel, and the barrel is mounted to the cylinder portion.

11. A digital camera module comprising:
a carrier comprising a base board with a top surface;
a chip disposed on the top surface, the chip comprising an active area and a plurality of pads disposed on a top surface thereof;
an adhesive applied to a peripheral circumference of the top surface of the chip, around the active area;
a cover adhered to the adhesive and supported above the chip by a supporting member, the cover and the adhesive cooperatively closing the active area of the chip;
a holder comprising a seat portion and a lens for forming a focused image on the active area of the chip, the seat portion comprising an inner circumferential wall attached to the cover by adhesive, and an outer circumferential wall attached to the carrier by adhesive;
a plurality of top contacts arranged at contacting area between the outer circumferential wall and the carrier; and
a plurality of wires respectively electrically connecting one of the pads to a corresponding top contact.

12. The digital camera module as claimed in claim 11, wherein the inner circumferential wall defines a recess receiving a peripheral edge of the cover in a manner that the inner circumferential wall surrounds the cover and tightly contacts with the peripheral edge of the cover.

13. The digital camera module as claimed in claim 11, wherein the carrier further comprises a side wall extending from a periphery of the top surface of the base board and surrounding the chip, the outer circumferential wall of the holder being attached to the side wall.

14. The digital camera module as claimed in claim 11, wherein the holder further comprises a cylinder portion rotatably mounted to the seat portion, the lens being mounted in the cylinder portion.

15. The digital camera module as claimed in claim 11, wherein the supporting member extends from the peripheral circumference of the top surface of the chip through the adhesive applied on the chip to contact with a face of the cover facing the chip.

16. The digital camera module as claimed in claim 11, wherein the pads are covered by the adhesive applied on the chip.
